(19) United States
(12) Patent Application Publication
(10) Pub. No.: US 2010/0108343 A1
(43) Pub. Date: May 6, 2010

(54) HOUSING AND MANUFACTURING METHOD THEREOF

(75) Inventors: Qin-Zheng Hou, Shenzhen City (CN); Gang Huang, Shenzhen City (CN); Yan-Min Wang, Shenzhen City (CN); Qiang Wang, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/553,480

(22) Filed: Sep. 3, 2009

(30) Foreign Application Priority Data
Oct. 31, 2008 (CN) 200810305349.0

(51) Int. Cl. H05K 5/02; B05D 1/36

(52) U.S. Cl. 174/50; 427/294; 427/296; 427/295

(57) ABSTRACT

A housing, comprising: a substrate; and a vacuum depositing coating formed on the substrate by vacuum depositing method, the vacuum depositing coating including a first metal coating, a second metal coating formed on the first metal coating, and a third metal coating formed on the second metal coating; wherein the first metal coating is an aluminum coating having a light transmittance of about 25-35%, the second metal coating is a silicon dioxide coating having a thickness of about 150-450 nm, and the third metal coating is a titanium coating having a light transmittance of about 45-55%. A method for making the housing is also described.

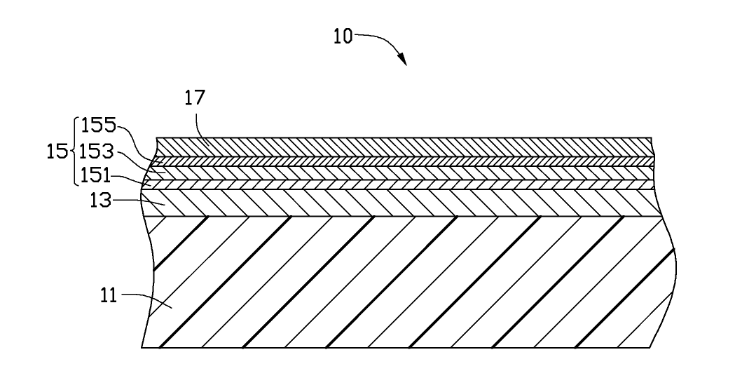

### BACKGROUND

1. Technical Field

The present disclosure relates to a housing and a manufacturing method thereof.

2. Description of Related Art

Housings of portable electronic devices are commonly made of plastic or metal. These housings are usually subjected to a surface treatment to form colorful or protective coatings thereon. The surface treatment method may be spray painting, electrophoretic depositing, or vacuum depositing. The coating formed by vacuum depositing can present attractive metallic appearance. Therefore, the vacuum depositing method is widely used. However, the coating formed by vacuum depositing method now can only present a single color. Furthermore, the coating cannot present different colors at a different observing direction.

Therefore, there is room for improvement within the art.

### BRIEF DESCRIPTION OF THE FIGURE

Many aspects of the housing can be better understood with reference to the following figure. The components in the figure are not necessarily drawn to scale, the emphasis instead being placed upon clearly illustrating the principles of the housing. Moreover, in the drawing like reference numerals designate corresponding parts throughout the several views.

The FIGURE is a cross-sectional view of a present embodiment of a housing.

### DETAILED DESCRIPTION

Referring to the FIGURE, in an exemplary embodiment, a housing 10 includes a substrate 11, a base paint coating 13 formed on one surface of the substrate 11, a vacuum depositing coating 15 formed on the base paint coating 13, and a top paint coating 17 formed on the vacuum depositing coating 15.

The substrate 11 may be made of plastic selected from a group consisting of polyethylene (PE), polyamide (PA), polycarbonate (PC), acrylonitrile-butadiene-styrene (ABS), polymethyl methacrylate (PMMA), and polyethylene terephthalate (PET). Alternatively, the substrate 11 may be made of metal.

The base paint coating 13 is an ultraviolet curing paint coating. The ultraviolet curing paint may be polyurethane acrylate paint. The ultraviolet curing paint may contain polyurethane acrylate pre-polymer, ultraviolet initiation agent(s), and additive agent(s). The base paint coating 13 has a smooth and glossy surface. The base paint coating 13 has a mirror reflection to light.

The vacuum depositing coating 15 is formed by vacuum depositing method. The vacuum depositing coating 15 may include a first metal coating 151, a second metal coating 153, and a third metal coating 155.

The first metal coating 151 is directly formed on the base paint coating 13. The first metal coating 151 may be an aluminum coating. The light transmittance of the first metal coating is about 25-35%, preferably, 30%.

The second metal coating 153 is formed on the first metal coating 151. The second metal coating 153 may be a silicon dioxide coating. The thickness of the second metal coating 153 is about 150-450 nm. The second metal coating 153 can present different colors at a different thickness in a range of about 150-450 nm.

The third metal coating 155 is formed on the second metal coating 153. The third metal coating 155 may be a titanium coating. The light transmittance of the third metal coating is about 45-55%, preferably, 50%.

The combination of the first metal coating 151, the second metal coating 153, and the third metal coating 155 can achieve different refractions and reflections to light at different observing directions by using the above-mentioned materials, light transmittance and thickness of the three metal coatings, thus makes the vacuum depositing coating 15 present different colors at different observing directions to obtain a more attractive housing 10. The base paint coating 13 can mirror reflect light, by which the gloss of the vacuum depositing coating 15 is enhanced.

It should be understood, the vacuum depositing coating 15 can also be directly formed on the substrate 11, i.e., the first metal coating 151 is directly formed on the substrate 11.

The top paint coating 17 is transparent. The paint used in the top paint coating 17 may be ultraviolet curing paint, polyurethane paint or unsaturated polyester paint. In this embodiment, ultraviolet curing paint is the preferred paint for the top paint coating 17. The top paint coating 17 has a high rigidity and can protect the vacuum depositing coating 15 from abrasion or scratch.

A method for making the housing 10 may comprise the following steps: providing a substrate; vacuum depositing a first metal coating using aluminum on one surface of the substrate, the first metal coating having a light transmittance of about 25-35%; vacuum depositing a second metal coating using silicon dioxide on the first metal coating, the second metal coating having a thickness of about 150-450 nm; vacuum depositing a third metal coating using titanium on the second metal coating, the third metal coating having a light transmittance of about 45-55%. Each step is described in more detail below.

A substrate 11 is provided. The substrate 11 may be made of plastic selected from a group consisting of polyethylene (PE), polyamide (PA), polycarbonate (PC), acrylonitrile-butadiene-styrene (ABS), polymethyl methacrylate (PMMA), and polyethylene terephthalate (PET). Alternatively, the substrate 11 may be made of metal.

A base paint coating 13 is applied on one surface of the substrate 11. The base paint coating 13 is an ultraviolet curing paint coating. The ultraviolet curing paint may be polyurethane acrylate paint. The ultraviolet curing paint may contain polyurethane acrylate pre-polymer, ultraviolet initiation agent(s), and additive agent(s).

A vacuum depositing coating 15 is applied on the base paint coating 13 by vacuum depositing method. Forming the vacuum depositing coating 15 may include the steps of forming the first metal coating 151, the second metal coating 153, and the third metal coating 155.

An aluminum coating is vacuum deposited onto the base paint coating 13 to form the first metal coating 151. The light transmittance of the first metal coating 151 is about 25-35%, preferably, 30%.

A silicon dioxide coating is vacuum deposited onto the first metal coating 151 to form the second metal coating 153. The thickness of the second metal coating 153 is about 150-450 nm. The second metal coating 153 can present different colors at a different thickness in a range of about 150-450 nm.

A titanium coating is vacuum deposited onto the second metal coating 153 to form the third metal coating 155. The light transmittance of the third metal coating 155 is about 45-55%, preferably, 50%.

A top paint coating 17 is applied on the third metal coating 155 by spray painting. The paint used in forming the top paint coating 17 may be ultraviolet curing paint, polyurethane paint or unsaturated polyester paint. In this embodiment, ultraviolet curing paint is the preferred paint for the paint coating 17. The top paint coating 17 has a high rigidity and can protect the vacuum depositing coating 15 from abrasion or scratch.

It should be understood, however, that even though numerous characteristics and advantages of the present embodiments have been set forth in the foregoing description, together with details of functions of the embodiments, the disclosure is illustrative only, and changes may be made in detail within the principles of the invention to the full extent indicated by the broad general meaning of the terms in which the appended claims are expressed.

What is claimed is:

1. A housing, comprising:
a substrate; and
a vacuum depositing coating formed on the substrate by vacuum depositing method, the vacuum depositing coating including a first metal coating, a second metal coating formed on the first metal coating, and a third metal coating formed on the second metal coating;
wherein the first metal coating is an aluminum coating having a light transmittance of about 25-35%, the second metal coating is a silicon dioxide coating having a thickness of about 150-450 nm, and the third metal coating is a titanium coating having a light transmittance of about 45-55%.

2. The housing as claimed in claim 1, wherein the substrate is made of transparent plastic selected from a group consisting of polyethylene, polyamide, polycarbonate, acrylonitrile-butadiene-styrene, polymethyl methacrylate, and polyethylene terephthalate.

3. The housing as claimed in claim 1, wherein the substrate is made of metal.

4. The housing as claimed in claim 1, wherein the housing further comprises a base paint coating formed between the substrate and the first metal coating; the base paint coating includes ultraviolet curing paint.

5. The housing as claimed in claim 1, wherein the housing further comprises a transparent top paint coating applied on the third metal coating, the top paint coating includes ultraviolet curing paint, polyurethane paint or unsaturated polyester paint.

6. A method for making a housing, comprising:
providing a substrate;
vacuum depositing a first metal coating using aluminum on one surface of the substrate, the first metal coating having a light transmittance of about 25-35%;
vacuum depositing a second metal coating using silicon dioxide on the first metal coating, the second metal coating having a thickness of about 150-450 nm; and
vacuum depositing a third metal coating using titanium on the second metal coating, the third metal coating having a light transmittance of about 45-55%.

7. The method as claimed in claim 6, wherein the substrate is made of transparent plastic selected from a group consisting of polyethylene, polyamide, polycarbonate, acrylonitrile-butadiene-styrene, polymethyl methacrylate, and polyethylene terephthalate.

8. The method as claimed in claim 6, wherein the substrate is made of metal.

9. The method as claimed in claim 6, wherein prior to the forming of the first metal coating, a base paint coating is applied onto the substrate.

10. The method as claimed in claim 6, wherein after the forming of the third metal coating, a transparent top paint coating is applied onto the third metal coating.

11. A method for making a housing, comprising:
providing a substrate;
forming a base paint coating on one surface of the substrate;
vacuum depositing a first metal coating using aluminum on the base paint coating, the first metal coating having a light transmittance of about 25-35%;
vacuum depositing a second metal coating using silicon dioxide on the first metal coating, the second metal coating having a thickness of about 150-450 nm;
vacuum depositing a third metal coating using titanium on the second metal coating, the third metal coating having a light transmittance of about 45-55%; and
forming a top paint coating on the third metal coating.
